(19) United States
(12) Patent Application Publication
(10) Pub. No.: US 2025/0169071 A1
(43) Pub. Date: May 22, 2025

(54) SEMICONDUCTOR MEMORY DEVICE AND METHOD OF MANUFACTURING THE SAME

(71) Applicant: SK hynix Inc., Icheon-si Gyeonggi-do (KR)

(72) Inventors: Do Young KIM, Icheon-si Gyeonggi-do (KR); Eun Mee KWON, Icheon-si Gyeonggi-do (KR)

(73) Assignee: SK hynix Inc., Icheon-si Gyeonggi-do (KR)

(21) Appl. No.: 18/659,532

(22) Filed: May 9, 2024

(30) Foreign Application Priority Data
Nov. 22, 2023 (KR) 10-2023-0163379

(51) Int. Cl. H10B 43/27; H01L 23/00; H01L 25/00; H01L 25/065; H01L 25/18; H10B 41/27; H10B 80/00

(52) U.S. Cl. CPC H10B 43/27; H01L 24/08; H01L 24/80; H01L 25/0657; H01L 25/18; H01L 25/50; H10B 41/27; H10B 80/00; H01L 2224/08145; H01L 2224/80895; H01L 2224/80896; H01L 2924/1431; H01L 2924/14511

(57) ABSTRACT

A semiconductor memory device includes a gate stack comprising interlayer insulating layers and conductive pattern layers alternately stacked on top of each other in a first direction. A channel structure is formed to pass through the gate stack and with an end that protrudes above the gate stack. A memory layer surrounds the channel structure, which has a core insulating layer. A channel layer surrounds the core insulating layer. A void is formed in the channel layer.

### CROSS-REFERENCE TO RELATED APPLICATION

The present application claims priority under 35 U.S.C. § 119(a) to Korean patent application number 10-2023-0163379 filed on Nov. 22, 2023, in the Korean Intellectual Property Office, the entire contents of which application is incorporated herein by reference.

### BACKGROUND

### 1. Technical Field

The present disclosure relates to an electronic device, and more particularly, to a semiconductor memory device comprising a vertical channel structure. The present disclosure also relates to a method of manufacturing such a memory device.

### 2. Related Art

Recently, a paradigm for a computer environment has been transformed into ubiquitous computing, which enables a computer system to be used almost anywhere. The uses of portable electronic devices such as mobile phones, digital cameras, and notebook computer is rapidly increasing. Those and other portable electronic devices generally use semiconductor memory systems, which use one or more semiconductor memory devices, that is, a data storage device. A data storage device is used as a main storage device or an auxiliary storage device for the portable electronic device.

A data storage device using a semiconductor memory device has advantages that include excellent data stability and excellent device durability because, unlike a magnetic hard disk drive or an optical memory device, a semiconductor memory device does not have or use any mechanical components. Data access time of a semiconductor memory device is also much shorter that the access time of even the fastest hard disk drives and optical drives. No less important is the much lower power consumption of a semiconductor memory device as compared to the power consumption of even the most energy-efficient hard disk drives and optical drives.

Semiconductor memory systems include data storage devices universal serial bus (USB) memory device, a memory card populated with semiconductor memory devices having various interfaces, solid state disk drive (SSD), and the like.

Semiconductor memory devices are generally categorized as either volatile memory devices or nonvolatile memory devices.

Write speed and read speed of nonvolatile memory devices are generally longer relative to the write speed and read speed of volatile memory devices, however, nonvolatile memory devices advantageously maintain data even after power to a nonvolatile memory device is shut off. A nonvolatile memory device is therefore used to store data that needs to be retained or maintained without requiring power.

Nonvolatile memory devices include read only memory (ROM), a mask ROM (MROM), a programmable ROM (PROM), an erasable programmable ROM (EPROM), an electrically erasable programmable ROM (EEPROM), a flash memory, a phase change random access memory (PRAM), a magnetic RAM (MRAM), a resistive RAM (RRAM), a ferroelectric RAM (FRAM), and the like. The flash memory is divided into a NOR type and a NAND type.

### SUMMARY

An embodiment of the present disclosure provides a semiconductor memory device and a method of manufacturing such a device by more uniformly forming a junction region of a vertical channel structure.

According to an embodiment of the present disclosure, a semiconductor memory device includes a gate stack including interlayer insulating layers and conductive pattern layers alternately stacked in a vertical direction on a substrate, a channel structure passing through the gate stack and having one end protruding above a top surface or top level of the gate stack, a memory layer surrounding a sidewall of the channel structure, and a source layer formed on the gate stack. The channel structure includes a core insulating layer extending in a vertical direction and formed in a central region, and a channel layer surrounding a sidewall of the core insulating layer and formed in the vertical direction higher than the memory layer. A VOID extending from a position lower than a lowest height of at least one conductive pattern layer corresponding to a source select line among the plurality of conductive pattern layers to a position higher than at least an uppermost height and located is included in the core insulating layer.

According to an embodiment of the present disclosure, a method of manufacturing a semiconductor memory device includes forming a memory cell array on a first substrate, so that the memory cell array includes a gate stack including interlayer insulating layers and conductive pattern layers alternately stacked in a vertical direction, a core insulating layer passing through the gate stack and having an end extending into the first substrate, a channel layer surrounding a sidewall and the end of the core insulating layer, and a memory layer extending from between the channel layer and the gate stack to between an end of the channel layer and the first substrate, removing the first substrate so that the memory layer is exposed, forming a junction at an upper end of the channel layer by performing an ion implantation process, and exposing the end of the channel layer by etching the exposed memory layer.

According to an embodiment of the present disclosure, a method of manufacturing a semiconductor memory device includes forming a memory cell array on a first substrate so that the memory cell array includes a gate stack including interlayer insulating layers and conductive patterns alternately stacked in a vertical direction, a core insulating layer passing through the gate stack and having an end extending into the first substrate, a channel layer surrounding a sidewall and the end of the core insulating layer, and a memory layer extending from between the channel layer and the gate stack to between an end of the channel layer and the first substrate, removing the first substrate so that the memory layer is exposed, exposing the end of the channel layer by removing the exposed memory layer, forming a spacer on an end sidewall of the channel layer, and forming a junction at an upper end of the channel layer by performing an ion implantation process.

According to an embodiment of the present disclosure, a method of manufacturing a semiconductor memory device includes forming a memory cell array on a first substrate so that the memory cell array includes a gate stack including interlayer insulating layers and conductive patterns alternately stacked in a vertical direction, a core insulating layer passing through the gate stack and having an end extending into the first substrate, a channel layer surrounding a sidewall and the end of the core insulating layer, and a memory layer extending from between the channel layer and the gate stack to between an end of the channel layer and the first substrate, removing the first substrate so that the memory layer is exposed, exposing the end of the channel layer by removing the exposed memory layer, forming a first source layer along a surface of the entire structure including the exposed end of the channel layer, forming a spacer on a sidewall of the first source layer extending in the vertical direction along a sidewall of the end of the channel layer, and forming a junction at an upper end of the channel layer by performing an ion implantation process.

According to an embodiment of the present disclosure, a method of manufacturing a semiconductor memory device includes: forming a memory cell array on a first substrate so that the memory cell array includes a gate stack including interlayer insulating layers and conductive pattern layers alternately stacked in a vertical direction, a core insulating layer passing through the gate stack and having an end extending into the first substrate, a channel layer surrounding a sidewall and the end of the core insulating layer, a memory layer configured of a blocking insulating layer, a data storage layer, and a tunnel insulating layer extending from between the channel layer and the gate stack to between an end of the channel layer and the first substrate, removing the first substrate so that the memory layer is exposed, exposing the data storage layer by removing the blocking insulating layer of the exposed memory layer, forming a spacer on a surface of the data storage layer, and forming a junction at an upper end of the channel layer by performing an ion implantation process.

According to the present technology, a junction region may be formed in a uniform depth in a channel layer, by performing an ion implantation process after forming a spacer on a side of a protruding vertical channel structure, after forming so that the vertical channel structure protrudes by passing through a gate stack.

### BRIEF DESCRIPTION OF THE DRAWINGS

FIG. 1 is a block diagram illustrating a semiconductor memory device according to an embodiment of the present disclosure.

FIG. 2 is a circuit diagram illustrating a memory cell array of FIG. 1.

FIG. 3 is a perspective view schematically illustrating a semiconductor memory device according to embodiments of the present disclosure.

FIG. 4 is a vertical cross-sectional view illustrating the memory cell array of FIG. 1.

FIGS. 5A to 5F, 6, 7, and 8A to 8D are vertical cross-sectional views illustrating a method of manufacturing a semiconductor memory device according to an embodiment of the present disclosure.

FIGS. 9A to 9D are vertical cross-sectional views illustrating a method of manufacturing a semiconductor memory device according to another embodiment of the present disclosure.

FIGS. 10A to 10D are vertical cross-sectional views illustrating a method of manufacturing a semiconductor memory device according to another embodiment of the present disclosure.

FIGS. 11A to 11D are vertical cross-sectional views illustrating a method of manufacturing a semiconductor memory device according to another embodiment of the present disclosure.

FIG. 12 is a block diagram illustrating a configuration of a memory system according to an embodiment of the present disclosure.

FIG. 13 is a block diagram illustrating a configuration of a computing system according to an embodiment of the present disclosure.

### DETAILED DESCRIPTION

Specific structural or functional descriptions of embodiments according to the concept which are disclosed in the present specification or application are illustrated only to describe the embodiments according to the concept of the present disclosure. The embodiments according to the concept of the present disclosure may be carried out in various forms and should not be construed as being limited to the embodiments described in the present specification or application.

Hereinafter, embodiments of the present disclosure will be described with reference to the accompanying drawings in order to describe in detail enough to allow those of ordinary skill in the art to easily implement the technical idea of the present disclosure.

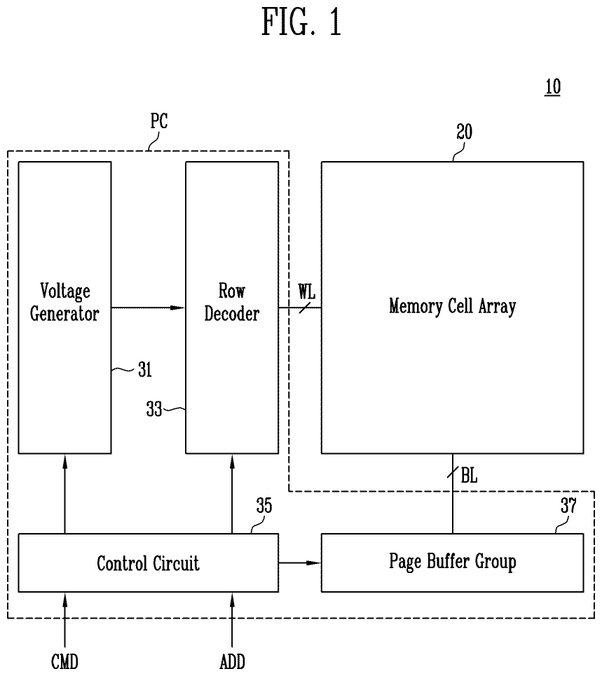

FIG. 1 is a block diagram illustrating a semiconductor memory device according to an embodiment of the present disclosure.

Referring to FIG. 1, the semiconductor memory device 10 includes a peripheral circuit PC and a memory cell array 20.

The peripheral circuit PC may be configured to control at least three different memory cell 20 operations: 1) a program operation for storing data in the memory cell array 20, 2) a read operation for outputting data stored in the memory cell array 20, and 3) an erase operation for erasing data stored in the memory cell array 20.

In a preferred embodiment, the peripheral circuit PC may include a voltage generator 31, a row decoder 33, a control circuit 35, and a page buffer group 37.

The memory cell array 20 may include a plurality of memory blocks, not shown in FIG. 1. The memory cell array 20 may be connected to the row decoder 33 through word lines WL. The memory cell array 20 may be connected to the page buffer group 37 through bit lines BL.

A control circuit 35 of the peripheral circuit PC may control the voltage generator 31, the row decoder 33, and the page buffer group 37 in response to a command CMD and an address ADD.

The voltage generator 31 may generate various operation voltages such as an erase voltage, a ground voltage, a program voltage, a verify voltage, a pass voltage, and a read voltage used for the program operation, the read operation, and the erase operation in response to control of the control logic 35.

The row decoder 33 may select a memory block in response to signals it receives from the control circuit 35. The row decoder 33 may be configured to apply operation voltages to word lines WL connected to the selected memory block.

The page buffer group 37 may be connected to the memory cell array 20 through the bit lines BL. The page buffer group 37 may temporarily store data received from an input/output circuit (not shown) during the program operation in response to the control of the control circuit 35. The page buffer group 37 may sense a voltage on or a current through one or more bit lines, BL, during the read operation or a verify operation in response to the control of the control circuit 35. The page buffer group 37 may select the bit lines BL in response to signals the page buffer group 37 receives from the control circuit 35.

Structurally, the memory cell array 20 may overlap a portion of the peripheral circuit PC.

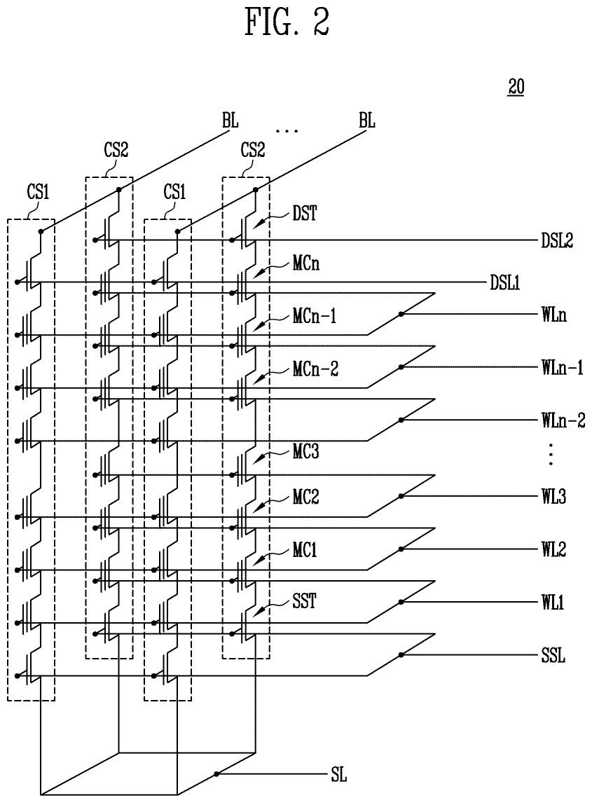

FIG. 2 is a perspective view of a circuit illustrating a memory cell array of FIG. 1.

Referring to FIG. 2, the memory cell array 20 may include a plurality of serially connected transistors, which are referred to herein cell strings CS1 and CS2. FIG. 2 depicts four (4), separate cell strings.

Each cell string CS1 and CS2 is connected between a source line SL depicted in FIG. 2 as being relatively close to the bottom edge of FIG. 2 and a plurality of bit lines BL, depicted in FIG. 2 as being relatively close to the top edge of FIG. 2. The gate terminal of each “cell” transistor of each string of the plurality of cell strings CS1 and CS2 is commonly connected to a plurality of word lines WL1 to WLn.

Each cell string of the plurality of cell strings CS1 and CS2 may include a source select transistor SST, said SST being located at the “bottom” of each cell string CS1, CS2, the gate terminal of which is connected to the source line SSL. The gate of a drain select transistor DST located at the “top” of each cell string CS1, CS2, is connected to the bit line BL. Several separate memory cells MC1 to MCn are connected in series to each other and thus form a string. Opposite ends of each string is connected between a corresponding source select transistor SST and a corresponding drain select transistor DST.

As shown in FIG. 2, gates of a transistor that comprises a memory cell MC of the plurality of memory cells MC1 to MCn, may is connected to a particular word line, WL, of a plurality of word lines denominated as WL1 to WLn, which are shown in FIG. 2 “vertically” stacked on top of each other such that the word lines, WL are considered to be vertically stacked and vertically spaced apart from each other by a separation distance between them.

Those of ordinary skill should of course recognize that vertical is generally known as or defined as “perpendicular to the plane of a horizon.” For purposes of this disclosure for claim construction purposes, designating the direction of word line stacking as “vertical” is for explanation purposes only. By way of example, if the structure depicted in FIG. 2 were to be re-drawn or simply rotated ninety degrees, the word lines of such a memory cell MC configuration would be stacked horizontally.

For claim construction purposed, “vertically” should not be construed as being perpendicular to the plane of a horizon. “Vertically” should be construed as a direction, i.e., the same direction, in which various structures may be oriented. As shown in FIG. 1, word lines WL1 to WLn may be connected located between the source select line SSL and two or more drain select lines DSL1 and DSL2. The two or more drain select lines DSL1 and DSL2 may be spaced apart from each other at the same level.

A gate of the source select transistor SST may be connected to a source select line SSL. A gate of the drain select transistor DST may be connected to a drain select line corresponding to the gate of the drain select transistor DST.

The source line SL may be connected to a source of the source select transistor SST. A drain of the drain select transistor DST may be connected to a bit line corresponding to the drain of the drain select transistor DST.

The plurality of cell strings CS1 and CS2 may be divided into string groups respectively connected to the two or more drain select lines DSL1 and DSL2. Cell strings connected to the same word line and the same bit line may be independently controlled by different drain select lines. In addition, cell strings connected to the same drain select line may be independently controlled by different bit lines.

As an embodiment, the two or more drain select lines DSL1 and DSL2 may include the first drain select line DSL1 and the second drain select line DSL2. The plurality of cell strings CS1 and CS2 may include a first cell string CS1 of a first string group connected to the first drain select line DSL1 and a second cell string CS2 of a second string group connected to the second drain select line DSL2.

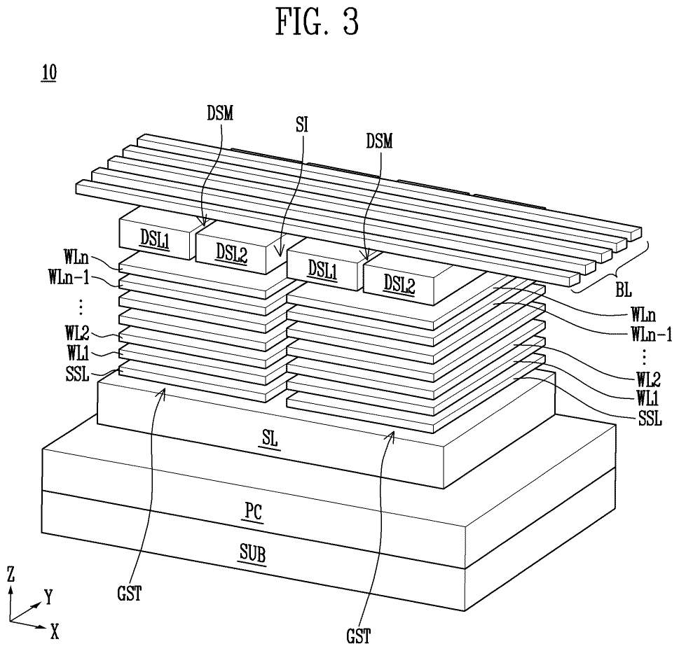

FIG. 3 is a perspective view schematically illustrating a semiconductor memory device 10 according to embodiments of the present disclosure.

Referring to FIG. 3, the semiconductor memory device 10 may include a peripheral circuit PC located on a substrate SUB. A source line SL, is formed on top of the substrate SUB. Two gate stacks GST are formed on top of the source line SL and within the “footprint” of the source line SL. The X and Y dimensions of the two gate stacks GST are thus less than the X and Y dimensions of the source line SL. The X and Y dimensions of the source line are less than the X and Y dimensions of the peripheral circuit PC. The X and Y dimensions of the peripheral circuit PC and the substrate SUB are the same or at least substantially the same. Each of the gate stacks GST may include the source select line SSL, a plurality of word lines WL1 to WLn, and two or more drain select lines DSL1 and DSL2 “horizontally” separated from each other, i.e., separated from each other in the X-direction, at the same “vertical” level, i.e., separated from the substrate SUB by substantially the same distance in the Z direction. By The separation space between the gate stacks GST being denominated as “DSM.”

As shown in FIG. 3, the source select line SSL, (depicted in FIG. 3 as the bottom “layer” of a gate stack) and the plurality of word lines WL1 to WLn, (stacked atop the source select line SSL) both extend in a first X-axis direction and a second Y-axis direction, orthogonal to the X-axis direction.

The source select line SSL and the word lines WL1-WLn have substantially the same shape, which is substantially the shape of a rectangular parallelepiped. A parallelepiped is well known as a 6-faced polyhedron, all faces of which are parallelograms, flat and lie in pairs of parallel planes. Each surface of the six surfaces that comprise the source select line SSL and the word lines WL1-WLn, is flat or substantially flat and said surface extends in two of the three mutually-orthogonal axes of an XYZ coordinate system.

The plurality of word lines WL1 to WLn may be considered as individual layers, vertically stacked on top of each other in a third Z-axis direction but also spaced apart from each other in said third Z-axis direction. The third Z-axis direction may be orthogonal to the X and Y axes directions of the-dimensional XYZ coordinate system faces. The plurality of word lines WL1 to WLn may be located between the two or more drain select lines DSL1 and DSL2 and the source select line SSL.

The gate stacks GST may be “horizontally” separated from each other in the X-axis direction by a slit SI between the gate stacks, which slit lies in a YZ plane. The X-axis direction width of the separation space DSM may be sized, shaped and arranged to be less that the X-direction width of the slit SI in the X direction.

When viewed in the Z-direction, the separation spaces one or both of the DSM spaces and the slit SI may have a shape, which may be substantially linear, saw-tooth, wave-like or sinusoidal. A X-axis width of each of the separation structure DSM and the slit SI may be variously changed according to a design rule.

The source select line SSL according to an embodiment may be located closer to the peripheral circuit PC than the two or more drain select lines DSL1 and DSL2.

The semiconductor memory device 10 may include the source line SL located between the gate stacks GST and the peripheral circuit PC, and the plurality of bit lines BL spaced farther from the peripheral circuit PC than the source line SL. The gate stacks GST may be located between the plurality of bit lines BL and the source line SL.

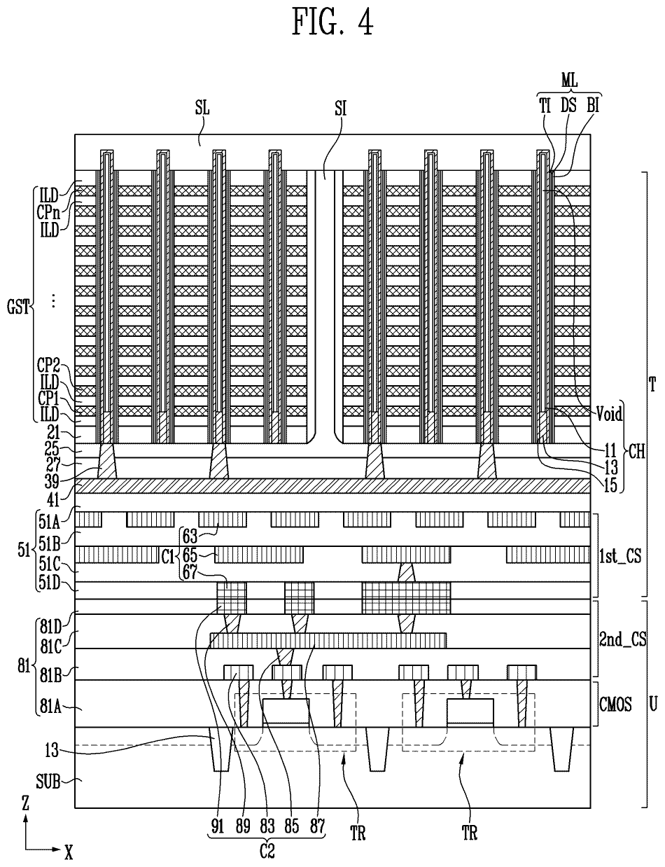

FIG. 4 is a vertical cross-sectional view illustrating the memory cell array of FIG. 1.

Referring to FIG. 4, in the memory cell array, a lower structure U and an upper structure T may be bonded to each other. The source line SL may be located on top of the upper structure T.

The upper structure T may include two gate stacks GST, as depicted in FIG. 3 as are two depicted in FIG. 4. In both figures, the gate stacks are separated from each other by the slit SI.

As shown in FIG. 4, the upper structure T may include “vertical” and substantially columnar channel structures CH, each of which passes through the stacked layers of the gate stacks. The upper structure also includes a substantially columnar memory layer ML formed around the outside surface or a “sidewall” of each channel structure CH. A bit line identified by reference numeral 41 is located under the gate stacks GST, and above a first connection structure C1.

The gate stack GST include interlayer insulating layers ILD and conductive pattern layers CP1 to CPn, which are alternately stacked on top of each other in a vertical, i.e., Z-axis direction. The conductive pattern CP layers in FIG. 4 are crosshatched.

Each of the conductive pattern layers CP1 to CPn may be made of various conductive materials such as a doped silicon layer, a metal layer, a metal silicide layer, and a barrier layer, and may include two or more types of conductive materials. For example, each of the conductive pattern layers CP1 to CPn may include tungsten and a titanium nitride (TiN) layer surrounding a surface of the tungsten. The tungsten may be a low-resistance metal and may have a resistance less than the resistance of the conductive pattern layers CP1 to CPn. The titanium nitride (TiN) may be a barrier layer and may prevent a direct contact between the tungsten and the interlayer insulating layers ILD.

Still referring to FIG. 4, a select line SL is located directly above and in contact with the uppermost insulating layer ILD, at the “top” of the gate stack. In FIG. 4, conductive pattern CP1 is the lowest conductive pattern CP in the gate stack and “sandwiched” between two insulating layers ILD. CP1 is thus the conductive pattern that is vertically farthest from the select line SL. Conductive pattern CP1 may be used as a drain select line DSL.

Of all the conductive pattern layers CP1 to CPn, the Z-axis level of the first (and lowest) conductive pattern CP1 in the gate stack is “higher” than the Z-axis level of the bit line 41. Conversely, the Z-axis level of the “highest” conductive pattern CPn, is several ILD/CP layer pairs above CP1 and separated from the select line SL by the uppermost insulating layer ILD. The CPn layer is thus separated from the select line SL by one insulating layer ILD.

In another embodiment, not shown, two or more layers of conductive patterns CP adjacent to the bit line 41 and successively stacked may be used as the drain select lines. Among the conductive pattern layers CP1 to CPn, the n-th conductive pattern CPn adjacent to the source line SL may be used as the source select line SSL. In another embodiment not shown, two or more layers of conductive pattern layers CP adjacent to the source line SL and successively stacked may be used as the source select lines, SSL. Conductive patterns (for example, CP2 to CPn-1) adjacent to each other in the vertical direction and located between the drain select line DSL and the source select line SSL may be used as the word lines WL1 to WLn described above with reference to FIG. 2.

In each embodiment, the channel structure CH passes through the gate stack GST in the vertical direction. One end of the channel structure CH may be formed to protrude or extend “above” the “top” of the gate stack GST.

The channel structure CH may be hollow and may have a circular or round horizontal cross-sectional shape. A length-wise portion of the interior of the channel structure CH is column shaped and empty. That length wise empty portion of the channel structure CH is a VOID. A VOID should therefore be construed as empty space, such as the empty space in the central or inner-most portion of a channel structure CH. For claim construction purposes, a VOID thus comprises a substantially column-shaped, empty space inside a channel structure CH.

In a preferred embodiment, a VOID has a substantially circular horizontal cross-sectional shape with a geometric center axis substantially parallel to the Z-axis in FIG. 4. A VOID is preferably formed around the geometric center axis of a channel structure CH. A VOID is also surrounded or substantially surrounded by a core insulating layer 11. A VOID is thus considered to be located in the “central region” of a channel structure.

A VOID is considered as having an upper portion, and a lower portion. A cylindrical plug-like doped semiconductor layer 13 is located near the bottom of the VOID and under the hollow, tube-shaped core insulating layer 11. Another hollow, tube-shaped channel layer 15 surrounds and contacts the outside surface of the hollow, tube-shaped core insulating layer 11. The hollow, tube-shaped channel layer 15 also surrounds and contacts the plug-like doped semiconductor layer 13.

The VOID is located inside the core insulating layer 11. The VOID and core insulating layer 11 around the VOID should extend from a level just below where the lowest conductive pattern layer CP1 are located in the gate stack upwardly in the Z-direction to a level just above, i.e., higher than, the uppermost conductive pattern layer, CPn are located in the gate stack. The VOID and the core insulating layer 11 thus extend through the gate stack.

For example, the VOID may extend from a position lower than at least one or more conductive patterns that may be used as the source select line to a position of a plurality of conductive pattern layers that may be used as the word lines or a position of at least one or more conductive pattern layers that may be used as the drain select line and may be located. The channel membrane 15 is used as a channel region of a cell string corresponding thereto. The channel layer 15 may be formed of a semiconductor material. As an embodiment, the channel layer 15 may include a silicon layer. A dopant may be implanted into a portion positioned at the uppermost portion of the channel layer 15, that is, a channel layer portion corresponding to the source select transistor, through an ion implantation process. The channel structure CH may be formed to protrude beyond the interlayer insulating layer ILD located in the uppermost portion of the gate stack GST.

The memory layer ML may be formed to surround a surface of the channel structure CH. The memory layer ML may include a tunnel insulating layer TI surrounding the channel layer 15 of the channel structure CH, a data storage layer DS surrounding the tunnel insulating layer TI, and a blocking insulating layer BI surrounding the data storage layer DS. The memory layer ML may extend in a direction perpendicular to the channel structure CH and may extend shorter than the channel layer 15. That is, the memory layer ML may be formed to have a height lower than that of the channel layer 15. That is, the channel layer 15 may have a height higher than that of the memory layer ML. The memory layer ML may be formed at the same height as the interlayer insulating layer ILD located in the uppermost portion of the gate stack GST. The memory layer ML may be defined as a component included in the channel structure CH.

The bit line 41 may be located under both gate stacks GST and may be electrically connected to the channel structure CH through contact plugs 39 passing “vertically” through a plurality of insulating layers 21, 25, and 27. The bit line 41 may be spaced apart from the substrate SUB by a first insulating structure 51 and a second insulating structure 81.

A first connection structure 1st_CS may include a first insulating structure 51 and first connection structures C1 formed inside the first insulating structure 51. The first connection structures C1 may include various conductive pattern layers 63, 65, and 67. The first insulating structure 51 may include two or more insulating layers 51A to 51D stacked between the bit line 41 and the second insulating structure 81.

The lower structure U may include a complementary metal oxide semiconductor (CMOS) circuit structure CMOS including a plurality of transistors TR formed on the substrate SUB. The lower structure U may also include a second connection structure 2nd_CS formed on the CMOS circuit structure CMOS.

The second connection structure 2nd_CS may include the second insulating structure 81 formed on the substrate SUB and second connection structures C2 formed inside the second insulating structure 81. Each of the second connection structures C2 may include various conductive pattern layers 83, 85, 87, 89, and 91 embedded in the second insulating structure 81. The second insulating structure 81 may include two or more insulating layers 81A to 81D sequentially stacked.

The upper structure T and the lower structure U may be bonded to each other through a conventional bonding process. For example, the exposed conductive pattern layers 67 of the first connection structure CS of the upper structure T and the exposed conductive pattern layers 91 of the second connection structure 2nd_CS of the lower structure U may be located to face each other and may be bonded to each other. The conductive pattern layer 67 and the conductive pattern layer 91 may be defined as a bonding metal.

As described above, the source line SL may be located on the upper structure T. The source line SL may be made of materials such as a dopant polysilicon layer or a metal material having a low resistance.

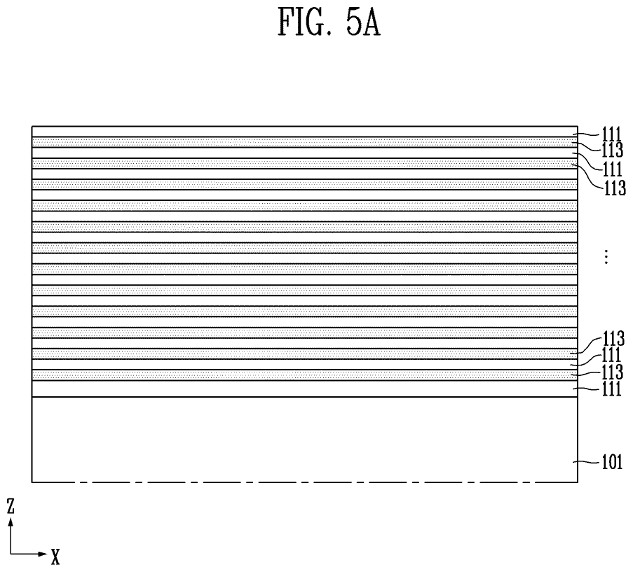

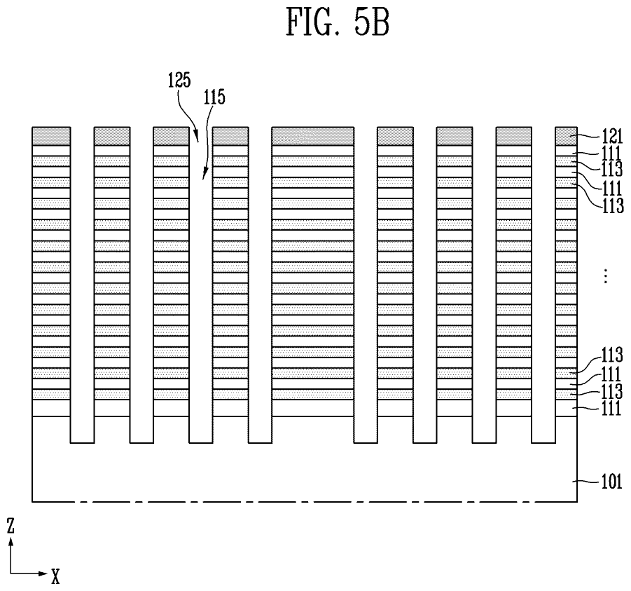

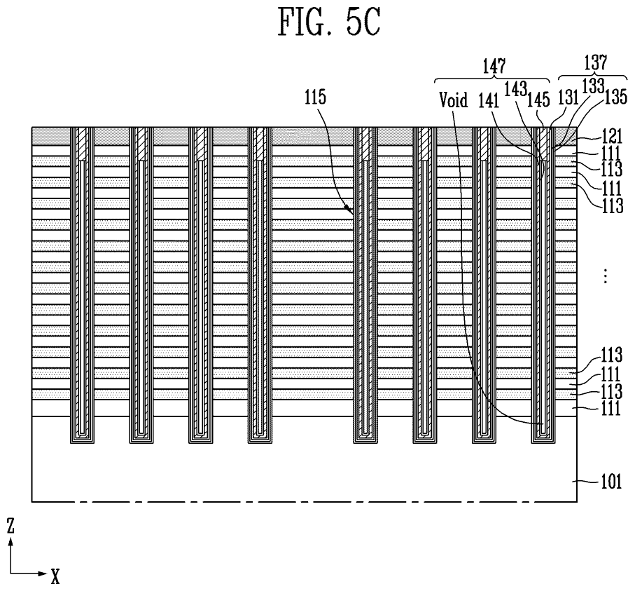

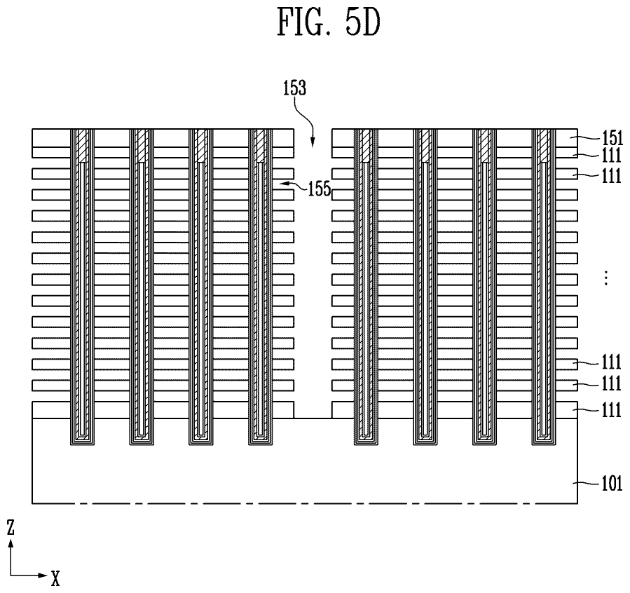

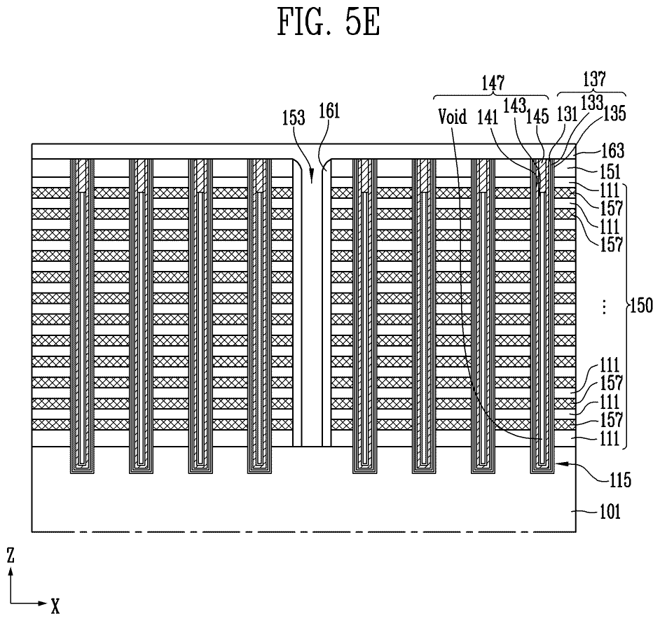

FIGS. 5A to 5F, 6, 7, and 8A to 8D are cross-sectional views illustrating a method of manufacturing a semiconductor memory device according to an embodiment of the present disclosure.

FIGS. 5A to 5F are cross-sectional views illustrating a step of forming a memory cell array, a first line array, and first connection structures on a first substrate.

Referring to FIG. 5A, first material layers 111 and second material layers 113 may be alternately stacked on top of each other, layer by layer, on a first substrate 101.

The first substrate 101 may be a material having an etching rate different from that of both the first material layers 111 and the second material layers 113. In one embodiment, the substrate 101 may include silicon.

The first material layer 111 may be an insulating material and used to provide the interlayer insulating layers ILD described above with reference to FIG. 4. The second material layer 113 may be a material having an etching rate different from that of the first material layers 111, such as silicon oxide or silicon nitride.

Properties of the first material layer 111 and properties of the second material layers 113 may be changed. For example, the first material layers 111 may be an insulating material for the interlayer insulating layers ILD described above with reference to FIG. 4, and the second material layers 113 may be a conductive material for the conductive pattern layers CP1 to CPn described above with reference to FIG. 4.

Referring to FIG. 5B, a first mask pattern 121 having first openings 125 may be formed on a stack structure made of the first material layers 111 and the second material layers 113. Channel holes 115 passing through the first material layers 111 and the second material layers 113 may be formed through the first openings 125 of the first mask pattern 121. The depth of the channel holes 115 may extend “downwardly” into the first substrate 101 to a partial depth. The etching method and the etching material that is used to form the channel holes 115 may determine the horizontal cross-sectional shape of the channel holes. The horizontal cross sectional shape may thus be made or formed to be circular or elliptical or even rectangular.

In one method of forming the channel holes, the channel holes 115 may be formed using a first etch material. An etching speed of the first material layers 111 and the second material layers 113 for the first etching material may be faster than an etching speed of the first substrate 101 for the first etching material. As a result, a width of an end of the channel holes 115 extending into the first substrate 101 may be formed to narrower than a width of the channel hole 115 passing through the first material layers 111 and the second material layers 113.

Referring to FIG. 5C, a memory layer 137 and a channel structure 147 may be formed inside the channel holes 115 by a deposition process. A sidewall of the channel structure 147 and an end of the channel structure 147 extending into the first substrate 101 may be surrounded by the memory layer 137.

Forming the memory “layer” 137, which is comprised of materials are deposited over a “vertical” surface of a channel hole 137, may include sequentially “stacking” a blocking insulating layer 135, a data storage layer 133, and a tunnel insulating layer 131 over the vertical surfaces of the channel holes 115. Each layer “stacked” over the surface of a vertically-oriented channel hole 115 may thus be considered a thin cylinder, each of which successively “lines” or covers the interior surface of a channel hole 115. The memory layer 137 may thus be considered a lining for a channel hole. The blocking insulating layer 135, the data storage layer 133, and the tunnel insulating layer 131 may be the same materials as the blocking insulating layer BI, the data storage layer DS, and the tunnel insulating layer TI described above with reference to FIG. 4.

A channel structure 147 may be formed by forming a channel layer 141 on the interior surface of the innermost layer of the memory layer 137. The channel layer 141 may include a semiconductor layer used as a channel region. For example, the channel layer 141 may include undoped polysilicon.

The channel layer 141 may also be considered a lining that provides a central region of the channel holes 115, which may include a hollow portion or region, which is not filled with the channel layer 141, which is the VOID described above.

When the channel layer 141 is formed as a lining, forming the channel structure 147 may fill the central region of the channel holes 115 with the core insulating layer 143 on the channel layer 141, and the VOID may be formed inside the core insulating layer 143. The VOID may be formed so that it extends from a level in the gate stack, which is at or near the lower end of the channel hole 115 inside the first substrate 101, upwardly in the Z-direction to an upper end of the channel hole 115, thereby passing through, i.e., extending through, both the first material layers 111 and the second material layers 113. For example, the VOID may be formed by extending from an elevation in the gate stack, which is below the lowest source select line to an elevation above the highest elevation of the gate stack. Stated another way, the VOID may be formed to extend from a height below the height of a subsequently formed source select line to a height of a subsequently formed drain select line.

During a process of filling the central region of the channel holes 115 with the core insulating layer 143, the VOID may be formed by first filling an opening portion of the channel hole 115 before a lower end of the channel hole 115 is completely filled. Thereafter, a portion of the core insulating layer 143 may be etched to define a recessed region in a portion of the central region of the channel holes 115, and the recessed region may be filled with a doped semiconductor layer 145.

The core insulating layer 143 may be a metal oxide. The doped semiconductor layer 145 may be a conductive dopant. The conductive dopant may include an n-type dopant for a junction as well as a counter-doped p-type dopant.

Referring to FIG. 5D, a first insulating layer 151 may be formed after removing the first mask pattern 121 shown in FIG. 5C. A slit 153 may then be formed.

The slit 153 may pass through the first insulating layer 151 and may pass through the stack structure of the first material layers 111 and the second material layers 113. The slit 153 in FIG. 5D corresponds to the slit SI shown in FIG. 4.

Horizontal spaces 155 are created by selectively removing the second material layers 113 exposed through the slit 153. The horizontal spaces 155 so created located between first material layers 111.

Referring to FIG. 5E, the horizontal spaces 155 shown in FIG. 5D are filled with a third type of material layers 157 via the slit 153. The third material layers 157 are the conductive pattern layers CP1 to CPn described above with reference to FIG. 4. The third material layers 157 substantial “fill” the horizontal spaces 155. The third material layers 157 also surround and make contact with the sidewall of channel structure 147 and the memory layer 137.

As described above, a gate stack 150 may be formed on the first substrate 101 by replacing the second material layers 113 as sacrificial layers with the third material layers 157 as conductive pattern layers. The gate stack 150 may include a structure in which the first material layers 111 are interlayer insulating layers ILD and the third material layers 157 as conductive pattern layers CPm. The ILD and CPm layers are alternately stacked on top of each other.

As stated above, the gate stack 150 layers be penetrated by the channel structure 147. The channel structure 147 may extend into the first substrate 101. The memory layer 137 may extend from between the channel structure 147 and the gate stack 150 to between an end of the channel structure 147 and the first substrate 101.

The third material layers 157, which comprise or “make up” the conductive pattern layers may be used as either a drain select line, SL, word lines WLm as well as a source select line, SSL. For example, one of the third material layers 157 formed to be conductive pattern layer, may be used as a source select line, SSL.

A memory block including the plurality of cell strings CS1 and CS2 described above with reference to FIG. 2 may be formed on the first substrate 101 through the processes described above with reference to FIGS. 5A to 5E. Each of the cell strings may include the drain select transistor DST, the memory cells MC1 to MCn, and the source select transistor SST connected in series, as described above with reference to FIG. 2. The drain select transistor DST, the memory cells MC1 to MCn, and the source select transistor SST described above with reference to FIG. 2 may be defined at intersections of the channel structure 147 shown in FIG. 5E and the third material layers 157 as the conductive pattern layers 157 and may be connected in series by the channel structure 147.

Next, a sidewall insulating layer 161 covering the sidewall of the gate stack 150 may be formed. Thereafter, a second insulating layer 163 filling an inside of the slit 153 and extending to cover the sidewall insulating layer 161 and the first insulating layer 151 may be formed.

Referring to FIG. 5F, a third insulating layer 171 may be formed on the second insulating layer 163. Subsequently, contact plugs 173 passing through the third insulating layer 171 or passing through the third insulating layer 171 and the second insulating layer 163 may be formed. The contact plugs 173 may extend to contact the channel structure 147.

Subsequently, the first line array 175 may be formed. The first line array 175 may be a bit line connected to the contact plug 173. Thereafter, a first insulating structure 181 covering the first line array 175 may be formed. The first insulating structure 181 may include two or more insulating layers 181A to 181D. First connection structures 185, 189, 191, and 193 may be buried inside the first insulating structure 181, and the first connection structures 185, 189, 191, and 193 may be electrically connected through contact plugs (not shown).

The first connection structures 185, 189, 191, and 193 may be made of a first bonding metal 193. The connection structures preferably have a surface exposed to an outside of the first insulating structure 181.

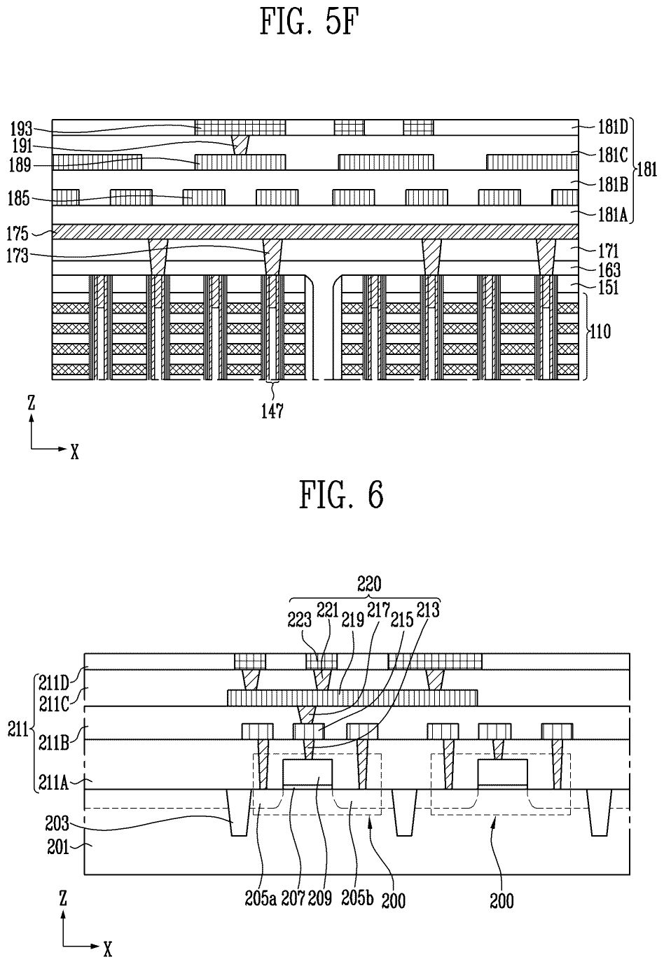

FIG. 6 is a vertical cross-sectional view of a portion of the lower part U, illustrating a step of forming a complementary metal oxide semiconductor (CMOS) circuit and second connection structures on a second substrate.

Referring to FIG. 6, a plurality of transistors 200 configuring the CMOS circuit on the second substrate 201 are formed.

The second substrate 201 may be a bulk silicon substrate, a silicon on insulator substrate, a germanium substrate, a germanium on insulator substrate, a silicon-germanium substrate, or an epitaxial layer formed through a selective epitaxial growth method.

Each of the transistors 200 may be formed in an active region of the second substrate 201 partitioned by an isolation layer 203. Each of the transistors 200 may include a gate insulating layer 207 and a gate electrode 209 stacked on an active region corresponding thereto, and junctions 205a and 205b formed in the active region on both sides of the gate electrode 209. The junctions 205a and 205b may include a conductive dopant to implement a transistor corresponding thereto. The junctions 205a and 205b may include at least one of an n-type dopant or a p-type dopant.

After forming the plurality of transistors 200, second connection structures 220 connected to the transistors 200 configuring the CMOS circuit, and second insulating structures 211 covering the second connection structures 220 and the transistors 200 may be formed.

The second insulating structure 211 may include two or more insulating layers 211A to 211D. The second connection structures 220 may be buried in the second insulating structure 211. Each of the second connection structures 220 may include a plurality of conductive pattern layers 213, 215, 217, 219, 221, and 223. The second insulating structure 211 and the second connection structures 220 are not limited to an example shown in the drawing and may be variously changed.

The conductive pattern layers 213, 215, 217, 219, 221, and 223 included in each of the second connection structures 220 may include a second bonding metal 223 having a surface exposed to an outside of the second insulating structure 211.

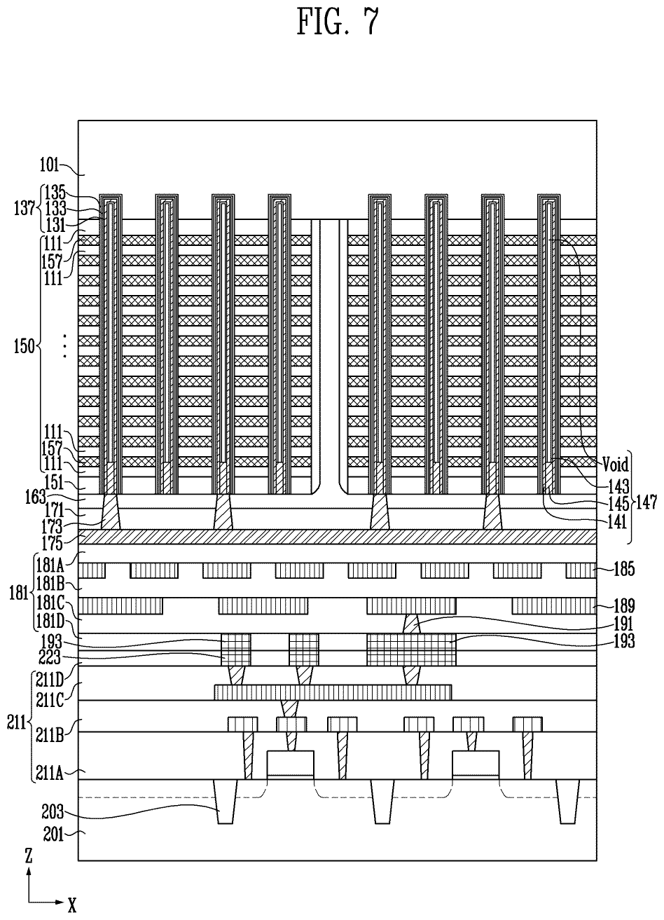

FIG. 7 is a vertical cross-sectional view of a gate stack illustrating a step of bonding the first connection structures and the second connection structures to each other.

Referring to FIG. 7, the first substrate 101 and the second substrate 201 are aligned so that a first bonding metal 193 on the first substrate 101 and a second bonding metal 223 on the second substrate 201 may be in contact with each other. The first bonding metal 193 and the second bonding metal 223 may include various metals, and may include, for example, copper.

Thereafter, the first bonding metal 193 and the second bonding metal 223 are bonded to each other. To this end, after heat is applied to the first bonding metal 193 and the second bonding metal 223, the first bonding metal 193 and the second bonding metal 223 may be hardened. The present disclosure is not limited thereto, and various processes for connecting the first bonding metal 193 and the second bonding metal 223 may be introduced.

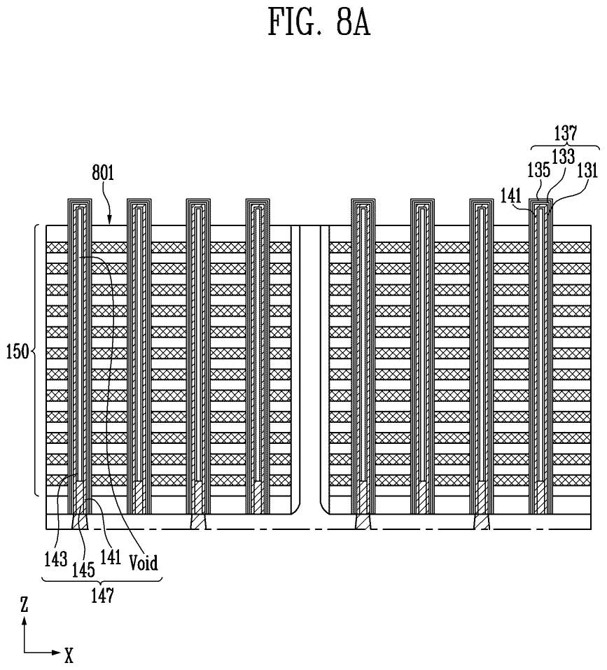

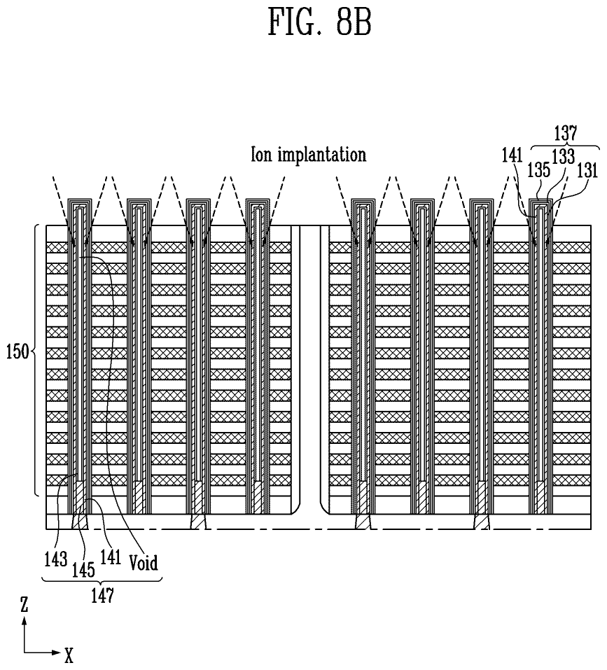

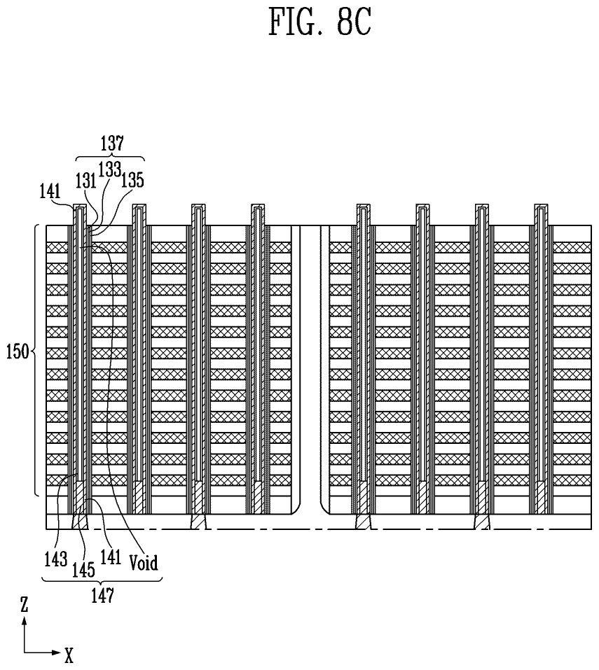

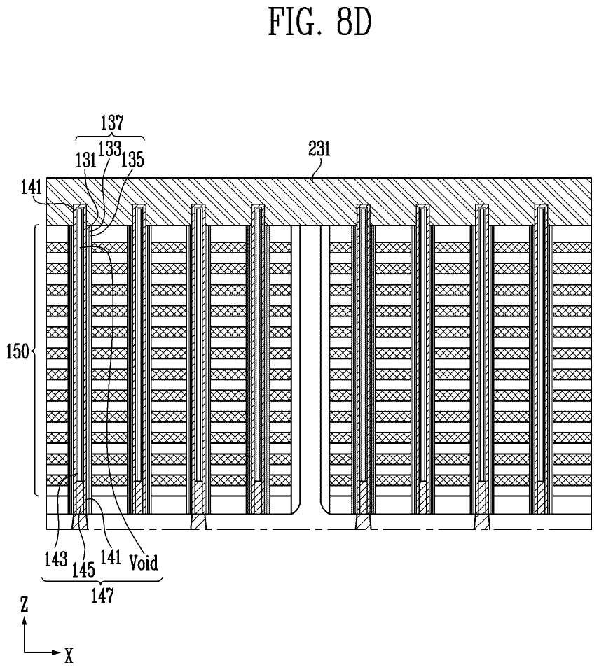

FIGS. 8A to 8D are vertical cross-sectional views illustrating a step of forming a source line connected to a plurality of cell strings on the gate stack 150.

Referring to FIG. 8A, the first substrate 101 shown in FIG. 7 may be removed. When the first substrate 101 is removed, the memory layer 137 may serve as an etch stop layer. Accordingly, the portion of the channel structure 147 protruding above the top surface 801 of the gate stack 150 may be protected by the memory layer 137.

In addition, during a process of removing the first substrate 101, the thickness of a first material layer located in the uppermost portion of the gate stack 150 may decrease.

Referring to FIG. 8B, a junction region is formed by implanting a dopant in the channel layer 141 utilized as a channel of the source select transistor by performing an ion implantation process in a state in which the portion of the channel structure 147 protruding above the “top” or uppermost surface of the gate stack is covered by the memory layer 137.

Due to the VOID inside the channel structure 147 of a region adjacent to the source select transistor, an ion implanted during the ion implantation process may pass through the channel layer 141, the core insulating layer 143, and the VOID, and may be implanted to a region except for a target region of the channel layer 141. In order to suppress that ion implantation, the ion implantation process is performed in a state in which the protruding channel structure 147 is covered by the memory layer 137.

Thereafter, the junction region is activated by performing a local heat treatment process using a laser. An object region of the heat treatment process may include the junction region of the channel layer 141 into which a dopant is implanted.

Referring to FIG. 8C, the channel layer 141 may be exposed by removing the memory layer 137 protruding above the gate stack 150. The exposed channel layer 141 may protrude above the top 801 of gate stack 150. An upper surface height of the memory layer 137 may be equal to or less than an upper surface height of the gate stack 150.

Referring to FIG. 8D, a source layer 231 (denominated as “SL” in FIG. 3 and FIG. 4) is formed on the entire gate stack structure including exposed surfaces of the channel layers 141. The source layer 231 may have a single-layer or multi-layer structure. For example, the source layer 231 may include first and second source layers, the first source layer may be formed of a doped polysilicon layer doped with a dopant, and the second source layer may be formed of a metal material having a low resistance. For example, the second source layer may be formed of titanium nitride (TiN) or tungsten (W) to reduce a resistance. In addition, the second source layer may be formed using copper (Cu), and may be configured by further including tantalum (Ta) or tantalum nitride (TaN) as a barrier layer on an upper surface and a lower surface of the second source layer.

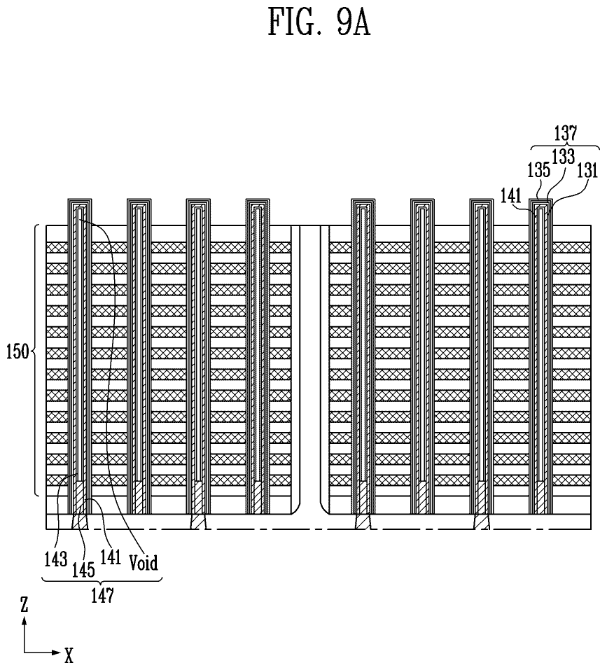

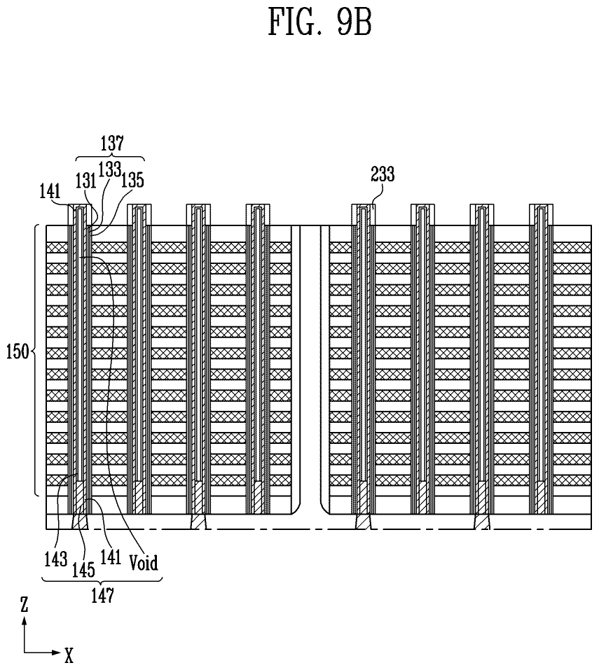

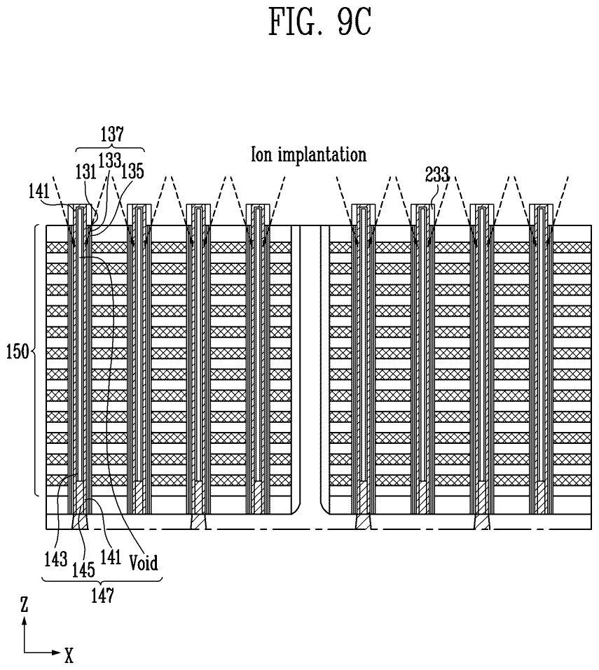

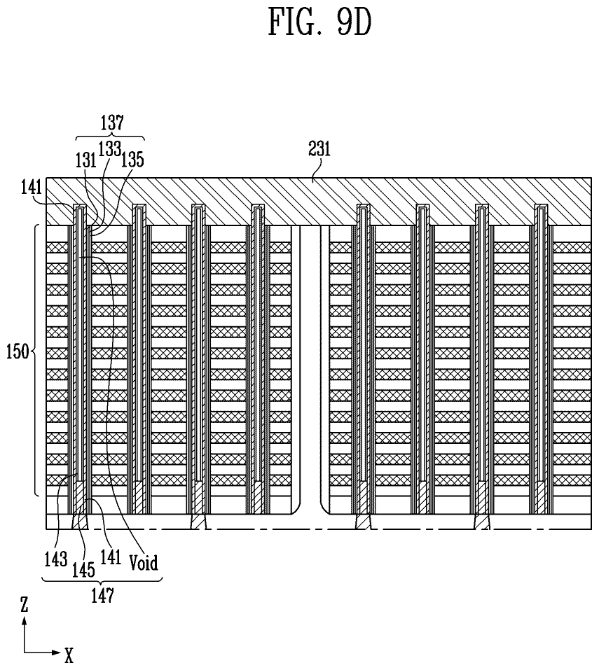

FIGS. 9A to 9D are vertical cross-sectional views illustrating a method of manufacturing a semiconductor memory device according to another embodiment of the present disclosure.

FIGS. 9A to 9D are vertical cross-sectional views illustrating another embodiment of a process step of forming a source line connected to a plurality of cell strings on the gate stack 150 described with reference to FIGS. 8A to 8D.

Referring to FIG. 9A, the first substrate 101 shown in FIG. 7 may be removed. When the first substrate 101 is removed, the memory layer 137 may serve as an etch stop layer.

Accordingly, the channel structure 147 protruding “beyond” or “above” or “top” of the gate stack 150 may be protected by the memory layer 137.

In addition, during a process of removing the first substrate 101, a thickness of the first material layer located in the uppermost portion of the gate stack 150 may be decreased.

Referring to FIG. 9B, the channel layer 141 may be exposed by removing the memory layer 137 protruding “above” or “beyond” the gate stack 150. The exposed channel layer 141 may protrude above the gate stack 150. An upper surface height of the memory layer 137 may be equal to or lower than an upper surface height of the gate stack 150.

Thereafter, a spacer 233 is formed on the side or “sidewall” of the protruding portion of the channel structure 147. For example, the spacer 233 may be formed by forming a spacer layer along a surface of the protruding channel structure 147 and performing an etching process so that the spacer layer remains only on the side or sidewall of the protruding channel structure 147. The spacer 233 may be formed of polysilicon.

Referring to FIG. 9C, a junction region is formed by implanting a dopant in the channel layer 141 utilized as a channel of the source select transistor by performing an ion implantation process in a state in which the spacer 233 is formed on the sidewall of the protruding channel structure 147.

Due to the VOID inside the channel structure 147 of a region adjacent to the source select transistor, an ion implanted during the ion implantation process may pass through the channel layer 141, the core insulating layer 143, and the VOID, and may be implanted to a region except for a target region of the channel layer 141. By forming the spacer 233 on the sidewall of the protruding channel structure 147, the ion implanted during the ion implantation process may be prevented from passing through the channel structure 147 and being implanted into a region except for the target region.

Thereafter, the junction region is activated by performing a local heat treatment process using a laser. An object region of the heat treatment process may include the junction region of the channel layer 141 into which a dopant is implanted.

Referring to FIG. 9D, after removing the spacer 233 of FIG. 9C, a source layer 231 is formed on the entire structure including the exposed surface of the channel layer 141.

The source layer 231 may have a single-layer or multi-layer structure. For example, the source layer 231 may include first and second source layers, the first source layer may be formed of a doped polysilicon layer doped with a dopant, and the second source layer may be formed of a metal material having a low resistance. For example, the second source layer may be formed of titanium nitride (TiN) or tungsten (W) to reduce a resistance. In addition, the second source layer may be formed using copper (Cu), and may be configured by further including tantalum (Ta) or tantalum nitride (TaN) as a barrier layer on an upper surface and a lower surface of the second source layer.

As another example, the spacer 233 of FIG. 9C may remain and may be used as the first source layer.

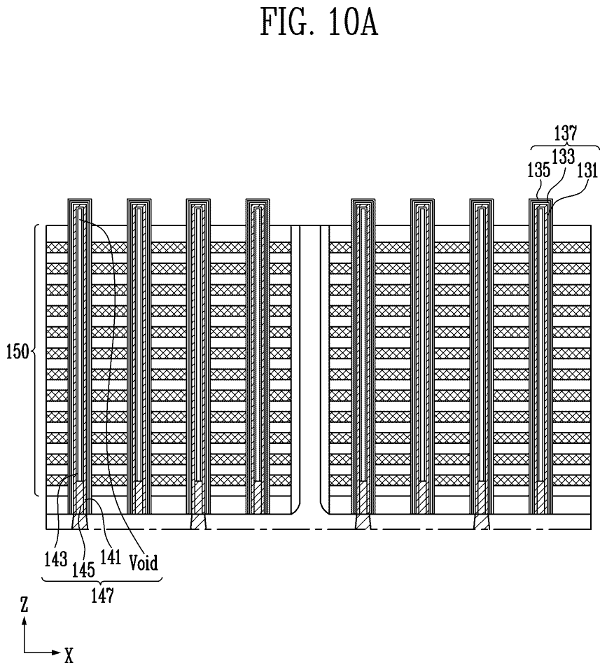

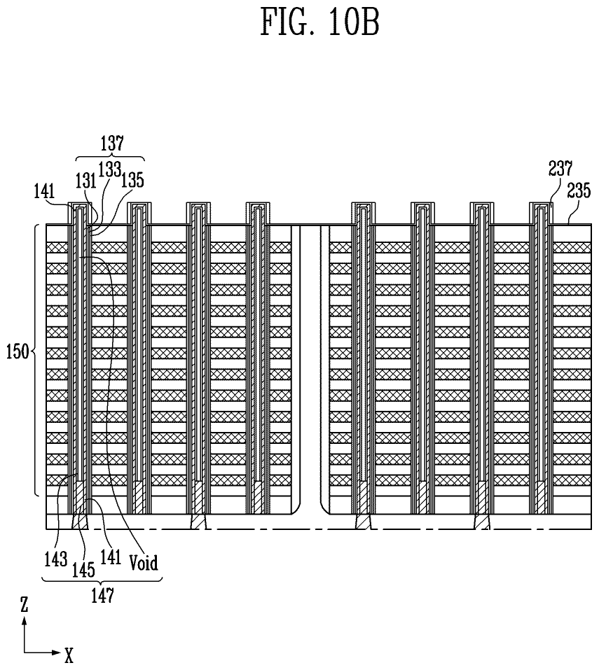

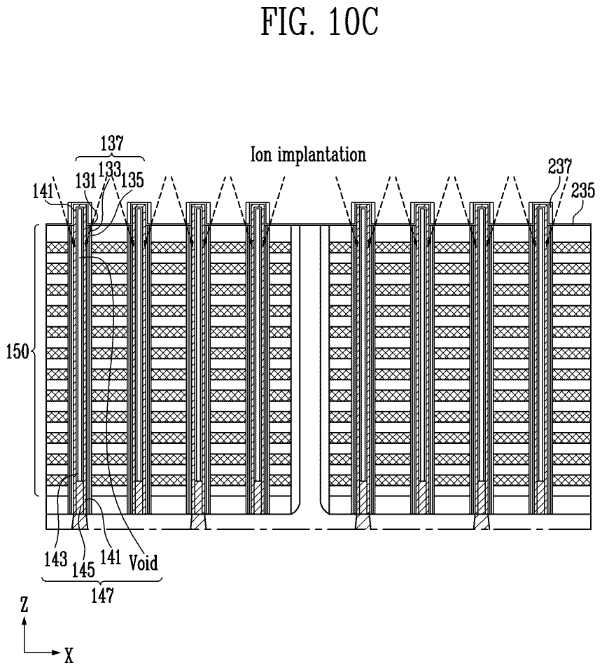

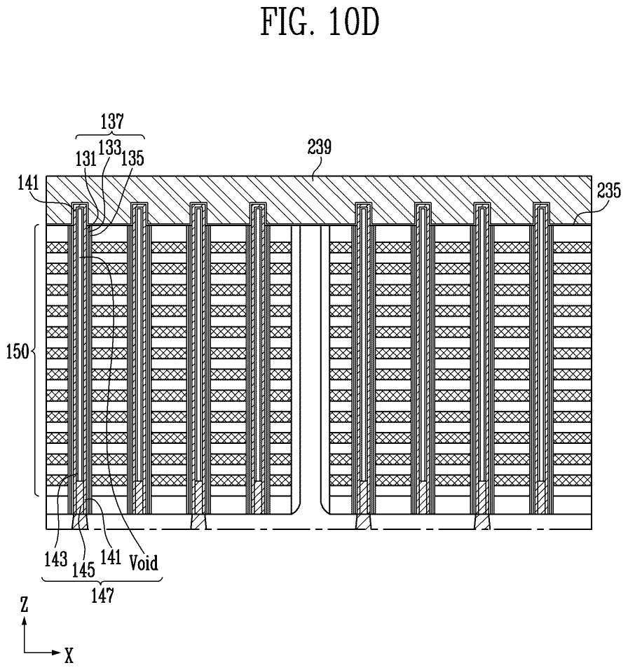

FIGS. 10A to 10D are vertical cross-sectional views illustrating a method of manufacturing a semiconductor memory device according to another embodiment of the present disclosure.

FIGS. 10A to 10D are vertical cross-sectional views illustrating still another embodiment of a process step of forming a source line connected to a plurality of cell strings on the gate stack 150 described with reference to FIGS. 8A to 8D.

Referring to FIG. 10A, the first substrate 101 shown in FIG. 7 may be removed. When the first substrate 101 is removed, the memory layer 137 may serve as an etch stop layer. Accordingly, the channel structure 147 protruding above the gate stack 150 may be protected by the memory layer 137.

In addition, during a process of removing the first substrate 101, a thickness of the first material layer located in the uppermost portion of the gate stack 150 may be decreased.

Referring to FIG. 10B, the channel layer 141 may be exposed by removing the memory layer 137 protruding above the gate stack 150. The exposed channel layer 141 may protrude above the gate stack 150. An upper surface height of the memory layer 137 may be equal to or lower than an upper surface height of the gate stack 150.

Thereafter, a first source layer 235 may be formed along the entire surface including the protruding channel structure 147. The first source layer 235 may be formed of a doped polysilicon layer doped with a dopant. Since the first source layer 235 is formed along the surface of the protruding channel structure 147, the first source layer 235 may include a portion extending in the vertical direction along the sidewall of the protruding channel structure 147.

Thereafter, a spacer 237 is formed on a sidewall of the first source layer 235 extending in the vertical direction along the sidewall of the protruding channel structure 147. The spacer 237 may be formed of an oxide layer.

Referring to FIG. 10C, a junction region is formed by implanting a dopant in the channel layer 141 utilized as a channel of the source select transistor by performing an ion implantation process in a state in which the first source layer 235 and the spacer 237 are formed on the sidewall of the protruding channel structure 147.

Due to the VOID inside the channel structure 147 of a region adjacent to the source select transistor, an ion implanted during the ion implantation process may pass through the channel layer 141, the core insulating layer 143, and the VOID, and may be implanted to a region except for a target region of the channel layer 141. By forming the first source layer 235 and the spacer 237 on the sidewall of the protruding channel structure 147, the ion implanted during the ion implantation process may be prevented from passing through the channel structure 147 and being implanted into a region except for the target region.

Thereafter, the junction region is activated by performing a local heat treatment process using a laser. An object region of the heat treatment process may include the junction region of the channel layer 141 into which a dopant is implanted.

Referring to FIG. 10D, after removing the spacer 237 of FIG. 10C, a second source layer 239 is formed on the first source layer 235.

The second source layer 239 may be formed of a metal material having a low resistance. For example, the second source layer 239 may be formed of titanium nitride (TiN) or tungsten (W) to reduce a resistance. In addition, the second source layer 239 may be formed using copper (Cu), and may be configured by further including tantalum (Ta) or tantalum nitride (TaN) as a barrier layer on an upper surface and a lower surface of the second source layer 239.

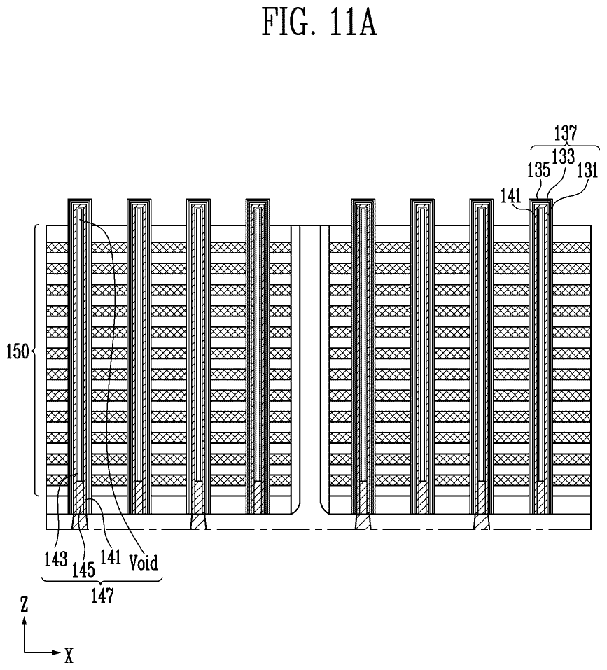

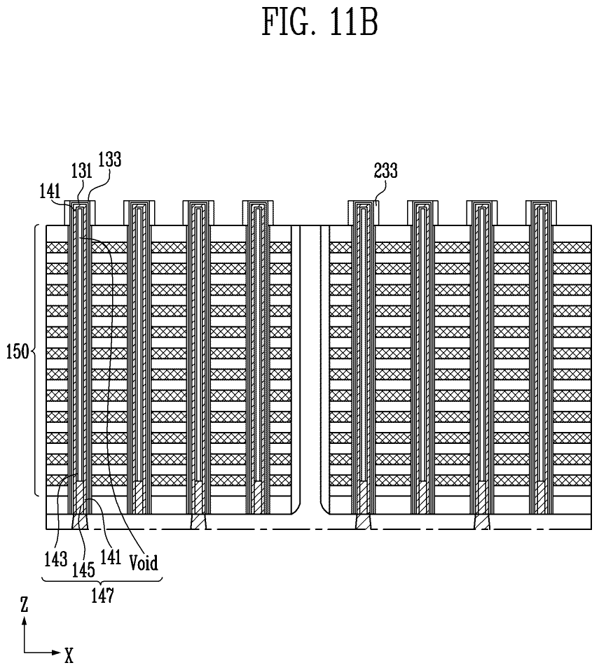

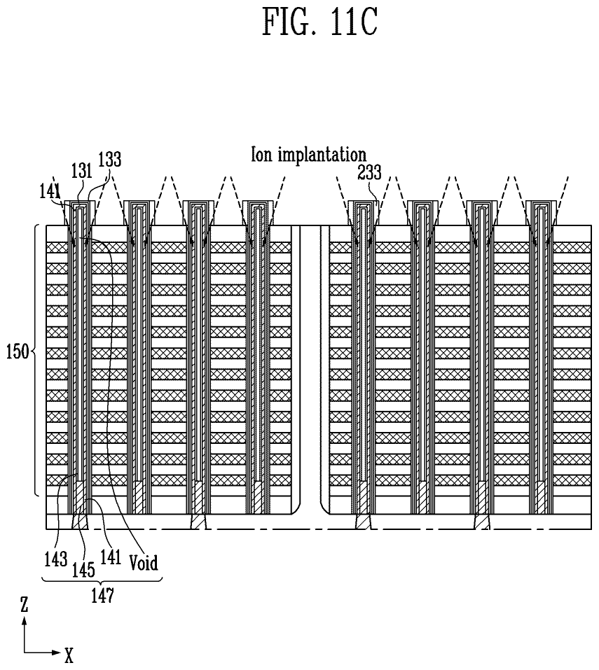

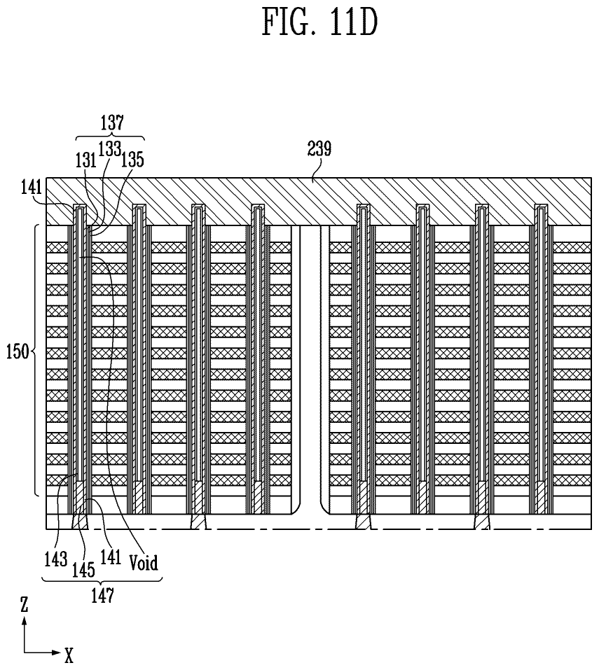

FIGS. 11A to 11D are vertical cross-sectional views illustrating a method of manufacturing a semiconductor memory device according to another embodiment of the present disclosure.

FIGS. 11A to 11D are vertical cross-sectional views illustrating still another embodiment of a process step of forming a source line connected to a plurality of cell strings on the gate stack 150 described with reference to FIGS. 8A to 8D.

Referring to FIG. 11A, the first substrate 101 shown in FIG. 7 may be removed. When the first substrate 101 is removed, the memory layer 137 may serve as an etch stop layer. Accordingly, the channel structure 147 protruding above the gate stack 150 may be protected by the memory layer 137.

In addition, during a process of removing the first substrate 101, a thickness of the first material layer located in the uppermost portion of the gate stack 150 may be decreased.

Referring to FIG. 11B, the data storage layer 133 is exposed by removing the blocking insulating layer 135 located in the outermost portion of the memory layer 137 protruding above the gate stack 150 and exposed.

Thereafter, a spacer 233 is formed on the exposed data storage layer 133. The spacer 233 may be formed in an area selective deposition (ASD) method. The spacer 233 may include silicon oxycarbide (SiOC).

Referring to FIG. 11C, a junction region is formed by implanting a dopant in the channel layer 141 utilized as a channel of the source select transistor by performing an ion implantation process in a state in which the tunnel insulating layer 131, the data storage layer 133, and the spacer 233 are formed on the sidewall of the protruding channel structure 147.

Due to the VOID inside the channel structure 147 of a region adjacent to the source select transistor, an ion implanted during the ion implantation process may pass through the channel layer 141, the core insulating layer 143, and the VOID, and may be implanted to a region except for a target region of the channel layer 141. By performing the ion implantation process in a state in which the tunnel insulting layer 131, the data storage layer 133, and the spacer 233 are formed on the sidewall of the protruding channel structure 147, the ion may be prevented from passing through the channel structure 147 and being implanted into a region except for the target region.

Thereafter, the junction region is activated by performing a local heat treatment process using a laser. An object region of the heat treatment process may include the junction region of the channel layer 141 into which a dopant is implanted.

Referring to FIG. 11D, the spacer 233 of FIG. 11C is removed. Thereafter, the exposed data storage layer 133 and tunnel insulating layer 131 are removed to expose the channel structure 147 protruding above the gate stack 150.

Thereafter, the source layer 231 is formed on the entire structure including the protruding channel structure 147.

The source layer 231 may have a single-layer or multi-layer structure. For example, the source layer 231 may include first and second source layers, the first source layer may be formed of a doped polysilicon layer doped with a dopant, and the second source layer may be formed of a metal material having a low resistance. For example, the second source layer may be formed of titanium nitride (TiN) or tungsten (W) to reduce a resistance. In addition, the second source layer may be formed using copper (Cu), and may be configured by further including tantalum (Ta) or tantalum nitride (TaN) as a barrier layer on an upper surface and a lower surface of the second source layer.

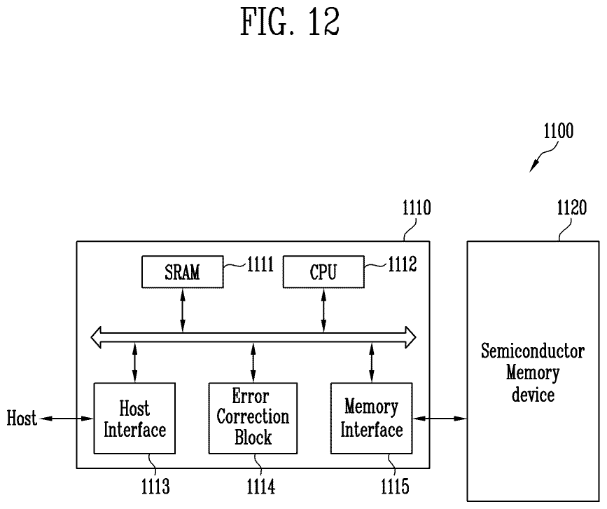

FIG. 12 is a block diagram illustrating a configuration of a memory system 1100 according to an embodiment of the present disclosure.

Referring to FIG. 12, the memory system 1100 includes a semiconductor memory device 1120 and a memory controller 1110.

The semiconductor memory device 1120 may be a multi-chip package configured of a plurality of flash memory chips. The semiconductor memory device 1120 may be the semiconductor memory device described with reference to FIGS. 1 to 4.

The memory controller 1110 may be configured to control the semiconductor memory device 1120, and may include a static random access memory (SRAM) 1111, a central processing unit (CPU) 1112, a host interface 1113, an error correction block 1114, and a memory interface 1115. The SRAM 1111 is used as an operation memory of the CPU 1112, the CPU 1112 performs an overall control operation for data exchange of the memory controller 1110, and the host interface 1113 include a data exchange protocol of a host connected to the memory system 1100. In addition, the error correction block 1114 detects and corrects an error included in data read from the semiconductor memory device 1120, and the memory interface 1115 performs interfacing with the semiconductor memory device 1120. In addition, the memory controller 1110 may further include a read only memory (ROM) that stores code data for interfacing with the host.

The above-described memory system 1100 may be a memory card or a solid state disk (SSD) in which the semiconductor memory device 1120 and the memory controller 1110 are combined. For example, when the memory system 1100 is the SSD, the memory controller 1110 may communicate with an outside (for example, a host) through one of various interface protocols such as a universal serial bus (USB), a multi-media card (MMC), a peripheral component interconnection-express (PCI-E), a serial advanced technology attachment (SATA), a parallel advanced technology attachment (PATA), a small computer system interface (SCSI), an enhanced small disk interface (ESD), and integrated drive electronics (IDE).

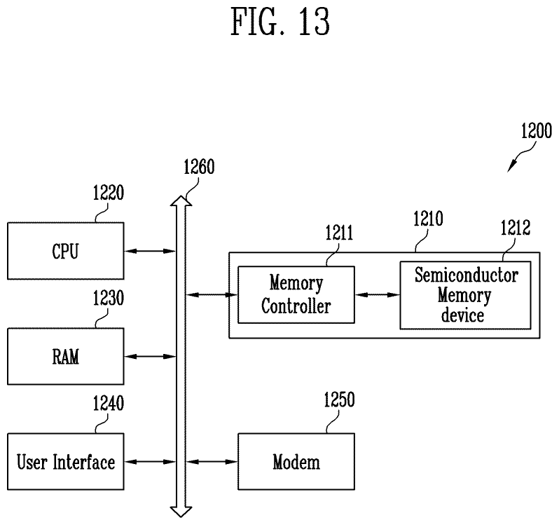

FIG. 13 is a block diagram illustrating a configuration of a computing system according to an embodiment.

Referring to FIG. 13, the computing system 1200 according to an embodiment or the present disclosure may include a CPU 1220, a random access memory (RAM) 1230, a user interface 1240, a modem 1250, and a memory system 1210 electrically connected to a system bus 1260. In addition, when the computing system 1200 is a mobile device, a battery for supplying an operation voltage to the computing system 1200 may be further included, and an application chipset, a camera image processor (CIS), a mobile DRAM, and the like may be further included.

The computing system 1200 may further include the memory system 1210, and the memory system 1210 may include a memory controller 1211 and a semiconductor memory device 1212.

The memory controller 1211 is configured to control the semiconductor memory device 1212, and the semiconductor memory device 1212 may be a multi-chip package configured of a plurality of flash memory chips. The semiconductor memory device 1212 may be the semiconductor memory device described with reference to FIGS. 1 to 4.

Although the detailed description of the present disclosure describes specific embodiments, various changes and modifications are possible without departing from the scope and technical spirit of the present disclosure. Therefore, the scope of the present disclosure should not be limited to the above-described embodiments, and should be determined by the equivalents of the claims of the present disclosure as well as the following claims.

What is claimed is:

1. A semiconductor memory device comprising:
a gate stack comprising interlayer insulating layers and conductive pattern layers, which are alternately stacked in a first direction, the alternately stacked layers being supported by a substrate;
a channel structure passing through the gate stack in the first direction, the channel structure having a protruding end, which extends above a top surface of the gate stack;
a memory layer surrounding the channel structure; and
a source layer formed on the gate stack,
wherein the channel structure comprises:
a core insulating layer having a hollow central region and which comprises a VOID; and
a channel layer surrounding the core insulating layer;
wherein, the VOID within the core insulating layer extends from a level below the lowest conductive pattern layer, upwardly in the first direction to a level, which is above the highest conductive pattern layer.

2. The semiconductor memory device of claim 1, wherein the source layer comprises:
a first source layer formed on an upper portion of the gate stack and around the protruding end of the channel structure; and
a second source layer formed on the first source layer.

3. The semiconductor memory device of claim 2, wherein a least a portion of the first source layer contacts an upper portion of the channel layer.

4. The semiconductor memory device of claim 2, wherein the first source layer is a doped polysilicon.

5. The semiconductor memory device of claim 2, wherein the second source layer is a low-resistance metal.

6. The semiconductor memory device of claim 1, wherein the channel layer includes a junction in a region adjacent to at least one conductive pattern corresponding to the source select line.

7. A method of manufacturing a semiconductor memory device, the method comprising:
forming a memory cell array on a first substrate, the memory cell array so formed comprising:
a gate stack comprising interlayer insulating layers and conductive pattern layers, which are alternately stacked on top of each other;
the memory cell array further comprising a core insulating layer passing through layers that comprise the gate stack orthogonally and having an end that extends into the first substrate;
a channel layer surrounding a sidewall and the end of the core insulating layer; and
a memory layer extending from between the channel layer and the gate stack to between an end of the channel layer and the first substrate;
the method further comprising the steps of:
removing the first substrate so that the memory layer is exposed;
forming a junction at an upper end of the channel layer by performing an ion implantation process; and
exposing the end of the channel layer by etching the exposed memory layer.

8. The method of claim 7, wherein the step of forming a memory cell array additionally comprises forming a VOID, which extends from a level in the gate stack which is below the lowest conductive pattern, upwardly through the gate stack, to a level that is above a top surface of the gates stack.

9. The method of claim 7, further comprising:
activating the junction by performing a local heat treatment process using a laser after the ion implantation process.

10. The method of claim 7, further comprising:
forming a source layer on an entire structure including the exposed end of the channel layer, after exposing the end of the channel layer.

11. The method of claim 10, wherein forming the source layer comprises:
forming a first source layer on the entire structure including the exposed end of the channel layer; and
forming a second source layer on the first source layer.

12. The method of claim 11, wherein the first source layer is a doped polysilicon and the second source layer is a low-resistance metal.

13. A method of manufacturing a semiconductor memory device, the method comprising:
forming a memory cell array on a first substrate, the memory cell array comprising:
a gate stack comprising interlayer insulating layers and conductive pattern layers, which are alternately stacked in a vertical direction;
a core insulating layer passing through the gate stack and having an end extending into the first substrate,
a channel layer surrounding a sidewall and the end of the core insulating layer, and
a memory layer extending from between the channel layer and the gate stack to between an end of the channel layer and the first substrate;
the method further comprising the steps of:
removing the first substrate so that the memory layer is exposed;
exposing the end of the channel layer by removing the exposed memory layer;
forming a spacer on an end sidewall of the channel layer; and
forming a junction at an upper end of the channel layer by performing an ion implantation process.

14. The method of claim 13, wherein forming the spacer comprises:
forming a spacer layer on an entire structure including the end of the channel layer; and
performing an etching process so that the spacer layer remains only the end sidewall of the channel layer.

15. The method of claim 13, wherein the spacer comprises polysilicon.

16. The method of claim 13, further comprising:
forming a source layer on an entire structure including the end of the channel layer, after forming the junction.

17. The method of claim 16, further comprising:
removing the spacer before forming the source layer.

18. A method of manufacturing a semiconductor memory device, the method comprising:
forming a memory cell array on a first substrate so that the memory cell array comprises a gate stack, said gate stack comprising interlayer insulating layers and conductive pattern layers alternately stacked in a vertical direction, a core insulating layer passing through the gate stack and having an end extending into the first substrate, a channel layer surrounding a sidewall and the end of the core insulating layer, and a memory layer extending from between the channel layer and the gate stack to between an end of the channel layer and the first substrate;
the method further comprising the steps of:
removing the first substrate so that the memory layer is exposed;
exposing the end of the channel layer by removing the exposed memory layer;
forming a first source layer along a surface of the entire structure including the exposed end of the channel layer;
forming a spacer on a sidewall of the first source layer extending in the vertical direction along a sidewall of the end of the channel layer; and
forming a junction at an upper end of the channel layer by performing an ion implantation process.

19. The method of claim 18, wherein the spacer is a metal oxide.

20. The method of claim 18, further comprising:
removing the spacer after forming the junction; and
forming a second source layer on the first source layer.

21. The method of claim 20, wherein the first source layer is a doped polysilicon and the second source layer is a low-resistance metal.

22. A method of manufacturing a semiconductor memory device, the method comprising:
forming a memory cell array on a first substrate so that the memory cell array comprises a gate stack, the gate stack so formed comprising interlayer insulating layers and conductive pattern layers alternately stacked in a vertical direction, a core insulating layer passing through the gate stack and having an end extending into the first substrate, a channel layer surrounding a sidewall and the end of the core insulating layer, a memory layer configured of a blocking insulating layer, a data storage layer, and a tunnel insulating layer extending from between the channel layer and the gate stack to between an end of the channel layer and the first substrate;
removing the first substrate so that the memory layer is exposed;
exposing the data storage layer by removing the blocking insulating layer of the exposed memory layer;
forming a spacer on a surface of the data storage layer; and
forming a junction at an upper end of the channel layer by performing an ion implantation process.

23. The method of claim 22, wherein the spacer is formed in an area selective deposition (ASD) method.

24. The method of claim 22, wherein the spacer comprises silicon oxycarbide (SiOC).

25. The method of claim 22, further comprising:
removing the spacer after forming the junction;
exposing the end of the channel layer by removing the exposed data storage layer and the tunnel insulating layer; and
forming a source layer on an entire structure including the end of the channel layer.

26. The method of claim 25, wherein forming the source layer comprises:
forming a first source layer on the entire structure including the exposed end of the channel layer; and
forming a second source layer on the first source layer.

27. The method of claim 26, wherein the first source layer is a doped polysilicon and the second source layer is a low-resistance metal.
